(19) United States
(12) Patent Application Publication
(10) Pub. No.: US 2012/0098092 A1
(43) Pub. Date: Apr. 26, 2012

(54) SEMICONDUCTOR DEVICE CAPACITORS INCLUDING MULTILAYERED LOWER ELECTRODES

(75) Inventors: Dongkyun PARK, Suwon-si (KR); Seonghwee CHEONG, Seoul (KR); Mansug KANG, Suwon-si (KR); Taekyun KIM, Suwon-si (KR); Heesook PARK, Hwaseong-si (KR)

(73) Assignee: Samsung Electronics Co., Ltd.

(21) Appl. No.: 13/271,821

(22) Filed: Oct. 12, 2011

(30) Foreign Application Priority Data
Oct. 22, 2010 (KR) 10-2010-0103532

(51) Int. Cl. H01L 29/92; H01L 23/48

(52) U.S. Cl. 257/532; 257/773; 257/E29.343; 257/E23.01

(57) ABSTRACT

A capacitor of a semiconductor device may include a lower electrode on a semiconductor substrate. A dielectric film can cover a surface of the lower electrode and an upper electrode can cover the dielectric film. The lower electrode can be a first conductive pattern that includes a bottom portion and a sidewall portion that defines a groove region. A core support pattern can be in the groove region of the first conductive pattern and a second conductive pattern can electrically connect to the first conductive pattern on the core support pattern.

### CROSS-REFERENCE TO RELATED APPLICATIONS

This U.S. non-provisional patent application claims priority under 35 U.S.C. §119 of Korean Patent Application No. 10-2010-01030532, filed on Oct. 22, 2010, the entire contents of which are hereby incorporated by reference.

### BACKGROUND

The present inventive concept herein relates to the field of electronics, and more particularly, to capacitors.

Capacitance of a capacitor is in proportion to a surface area of an electrode and a dielectric constant of a dielectric film and is in inverse proportion to an equivalent oxide thickness of dielectric film. Thus, as methods of increasing capacitance of a capacitor within a limited area, there are methods of increasing a surface area of electrode by forming a capacitor of three dimensional structure, reducing an equivalent oxide thickness of dielectric film and using a dielectric film having a high dielectric constant.

As methods of increasing a surface area of electrode, there are methods of increasing a height of a lower (or a storage) electrode, expanding an effective surface area of lower electrode using a hemi-spherical grain (HSG) and using the inside and outside area of cylinder using one cylindrical storage (OCS). As a dielectric film having a high dielectric constant, there may be a metal oxide film such as TiO₂ and TaO₅ or a ferroelectric of perovskite structure such as PZT(PbZrTiO₃) and BST(BaSrTiO₃).

### SUMMARY

Embodiments according to the inventive concept can provide semiconductor device capacitors including multilayered lower electrodes. Pursuant to these embodiments, a capacitor of a semiconductor device may include a lower electrode on a semiconductor substrate. A dielectric film can cover a surface of the lower electrode and an upper electrode can cover the dielectric film. The lower electrode can be a first conductive pattern that includes a bottom portion and a sidewall portion that defines a groove region. A core support pattern can be in the groove region of the first conductive pattern and a second conductive pattern can electrically connect to the first conductive pattern on the core support pattern.

In some embodiments according to the inventive concept, the capacitor may include a lower electrode on a semiconductor substrate and a dielectric film that covers a surface of the lower electrode. An upper electrode can cover the dielectric film. The lower electrode can include a first conductive pattern that defines a groove region and includes a bottom portion and a sidewall portion having a uniform thickness. A second conductive pattern can include a lower pattern that is disposed in the groove region and an upper pattern that is disposed on a top surface of the first conductive pattern.

In some embodiments according to the inventive concept, a lower electrode can include a first conductive pattern, on a semiconductor substrate of the device, that includes a groove region therein that is electrically contacting an underlying contact plug at a bottom of the first conductive pattern. A second conductive pattern, separate from the first conductive pattern, can extend into the groove region to the bottom of the first conductive pattern.

In some embodiments according to the inventive concept, a method of manufacturing a capacitor of semiconductor device including forming a lower electrode, a dielectric film and an upper electrode. Forming the lower electrode may include forming a first mold layer in which a first opening is defined. A first conductive film can be conformally formed to define a groove region in the first opening. A second mold layer can be formed in which a second opening that exposes the groove region is defined on the first mold layer. A second conductive film can be formed which is in contact with the first conductive film in the second opening.

### BRIEF DESCRIPTION OF THE DRAWINGS

FIGS. 1 through 11 are cross sectional views for explaining methods of manufacturing capacitors of semiconductor devices in accordance with embodiments of the inventive concept.

FIGS. 12 through 15 are cross sectional views for explaining methods of manufacturing capacitors of semiconductor devices in accordance with embodiment of the inventive concept.

FIGS. 16 through 20 are cross sectional views for explaining methods of manufacturing capacitors of semiconductor devices in accordance with embodiments the inventive concept.

### DETAILED DESCRIPTION OF EMBODIMENTS ACCORDING TO THE INVENTIVE CONCEPT

Preferred embodiments of the inventive concept will be described below in more detail with reference to the accompanying drawings. The embodiments of the inventive concept may, however, be embodied in different forms and should not be constructed as limited to the embodiments set forth herein. Rather, these embodiments are provided so that this disclosure will be thorough and complete, and will fully convey the scope of the inventive concept to those skilled in the art. Like numbers refer to like elements throughout.

In the drawings, the thickness of layers and regions are exaggerated for clarity. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Embodiments of the inventive concept may be described with reference to cross-sectional illustrations, which are schematic illustrations of idealized embodiments of the present invention. As such, variations from the shapes of the illustrations, as a result, for example, of manufacturing techniques and/or tolerances, are to be expected. Thus, embodiments of the present invention should not be construed as limited to the particular shapes of regions illustrated herein, but are to include deviations in shapes that result from, e.g., manufacturing. For example, a region illustrated as a rectangle may have rounded or curved features. Thus, the regions illustrated in the figures are schematic in nature and are not intended to limit the scope of the present invention.

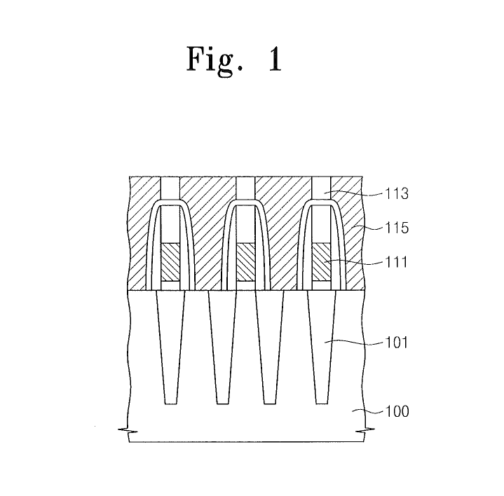

FIGS. 1 through 11 are cross sectional views for explaining methods of manufacturing capacitors of semiconductor devices in accordance with embodiments of the inventive concept.

Referring to FIG. 1, a plurality of transistors are formed on a semiconductor substrate 100 in which an active region is defined by a device isolation layer 101. The transistor may include a gate electrode and source/drain electrodes (not illustrated).

More specifically, the semiconductor substrate 100 may be a silicon substrate, a silicon-on-insulator (SOI) substrate, a germanium substrate, a germanium-on-insulator (GOI), a silicon-germanium substrate or an epitaxial thin film obtained by performing a selective epitaxial growth (SEG).

According to an embodiment of the inventive concept, a plurality of gate lines 111 crossing the active regions may be formed on the semiconductor substrate 100. Bit lines crossing the gate lines 111 may be formed on the gate lines 111. According to another embodiment of the inventive concept, a plurality of gate lines 111 may be recessed by a predetermined depth in a top surface of the substrate 100 and a plurality of bit lines may be arranged on the substrate 100. According to still another embodiment of the inventive concept, transistors having a vertical channel may be formed in the semiconductor substrate 100. In this case, the bit lines may cross sidewalls of the gate lines 111.

An interlayer insulating film 113 covering the gate lines 111 and the bit lines may be formed on the semiconductor substrate 100. More specifically, the interlayer insulating film 113 may comprise one or more insulating films and the insulating film may be formed from material having a superior gap fill characteristic. For example, the insulating film may be boron phosphor silicate glass (BPSG), a high density plasma (HDP) oxide film, a tetra ethyl ortho silicate (TEOS) film, undoped silicate glass (USG) or tonen silazene (TOSZ). The interlayer insulating film 113 may be formed using a film formation technology having a superior property of step coverage such as a chemical vapor deposition (CVD) or an atomic layer deposition (ALD). After depositing the interlayer insulating film 113, an upper portion of the interlayer insulating film 113 may be planarized by performing a chemical mechanical polishing (CMP) or an etch back process. Before forming the interlayer insulating film 113, an etch stop film 121 conformally covering structures formed on the semiconductor substrate 100.

Contact plugs 115 may be formed by patterning the interlayer insulating film 113 to form contact holes, and then filling the contact hole with conductive material. The contact holes exposing the source/drain electrodes formed on the semiconductor substrate may be formed by performing a photolithography process on the interlayer insulating film 113. Filling the contact holes with conductive material may include depositing a conductive film in the contact hole and planarizing the conductive film. Herein, the conductive film may be formed from at least one of a polysilicon film, a metal film, a metal nitride film and a metal silicide film.

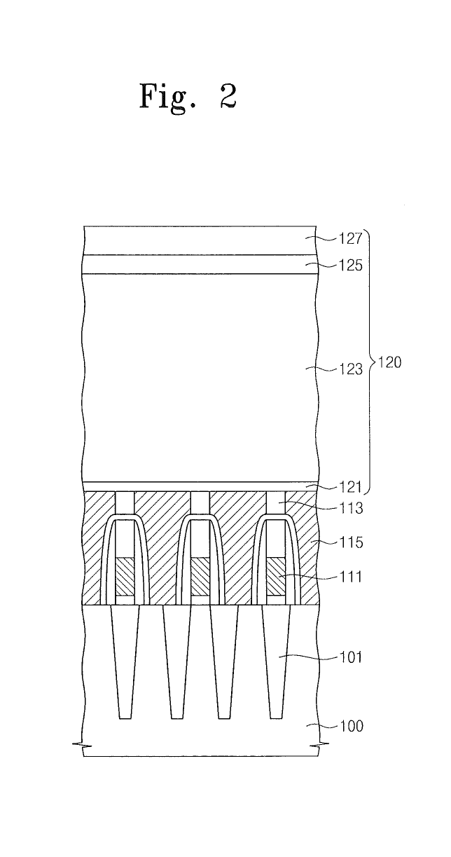

Referring to FIG. 2, a first mold layer 120 may be formed on the interlayer insulating film 113 including the contact plugs 115.

In forming a cylindrical capacitor, a height of lower electrode may become different depending on a thickness of the first mold layer 120 and capacitance of a capacitor may become different depending on a height of lower capacitor. That is, the more increases a height of the lower capacitor electrode, the more the capacitance of a capacitor increases. According to an embodiment of the inventive concept, the first mold layer 120 may have a thickness of about 5000 Å˜about 15000 Å.

According to an embodiment of the inventive concept, the first mold layer 120 may include a first support film 125 to form a support pattern for preventing a lower electrode of cylindrical type from collapsing. That is, in an embodiment of the inventive concept, the first mold layer 120 may be comprised of a lower insulating film 123, the first support film 125 and an upper insulating film 127. According to another embodiment of the inventive concept, the first support film 125 may be omitted and the first mold layer 120 may be comprised of one or a plurality of insulating films. More specifically, the lower insulating film 123 and the upper insulating film 127 may be formed from a silicon oxide film such as borosilicate glass (BSG), phosphosilicate glass (PSG), borophosphosilicate glass (BPSG), tetra ethyl ortho silicate (TEOS) or undoped silicate glass (USG). The first support film 125 may be formed from material having an etching selectivity with respect to the lower and upper insulating films 123 and 127 when performing a wet etching process on the lower and upper insulating films 123 and 127. For example, the lower and upper insulating films 123 and 127 may be formed from a silicon nitride film, a silicon carbon nitride film or a silicon oxynitride film and may have a thickness of about 100 Å˜1000 Å.

According to an embodiment of the inventive concept, before forming the lower insulating film 123, the etch stop film 121 (used as an etch end point when patterning the first mold layer 120) may be formed. The etch stop film 121 may have a thickness of about 100 Å˜500 Å and may be formed from, for example, a silicon nitride film or a silicon oxynitride film.

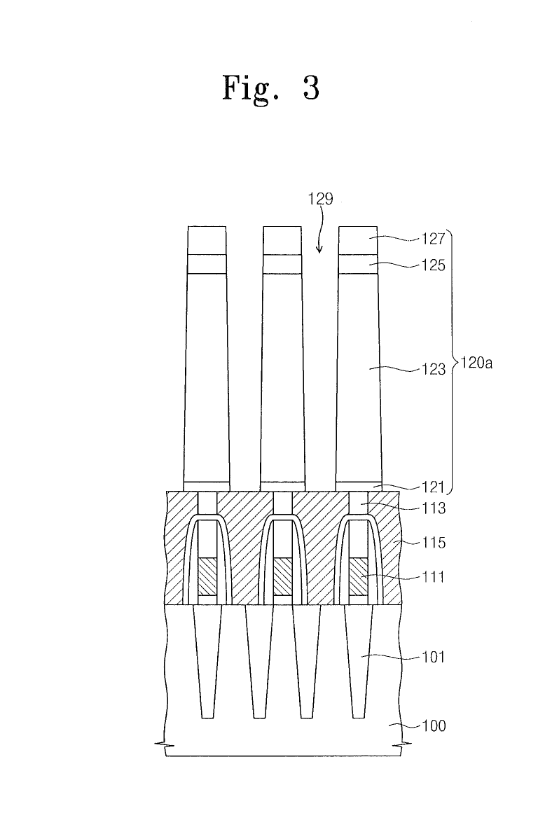

Referring to FIG. 3, the first mold layer 120 is patterned to form first openings 129 exposing the contact plugs 115. More specifically, to form the first openings 129 penetrating the thick first mold layer 120, a hard mask pattern having a superior etching selectivity with respect to the first mold layer 120 may be used while etching the first mold layer 120. The mask pattern may be formed from amorphous carbon and/or polysilicon. The first openings 129 may be formed by anisotropically etching the first mold layer 120 and the etching stop film 121 using the hard mask on the first mold layer 120 as an etching mask. Due to the anisotropic etching, the first opening 129 may have a tapered width that becomes narrower closer to the contact plug 115. That is, the first openings 129 may have inclined sidewalls. When anisotropically etching the first mold layer 120, the etching stop film 121 is removed by an over etching and thereby top surfaces of the contact plugs 115 may be exposed.

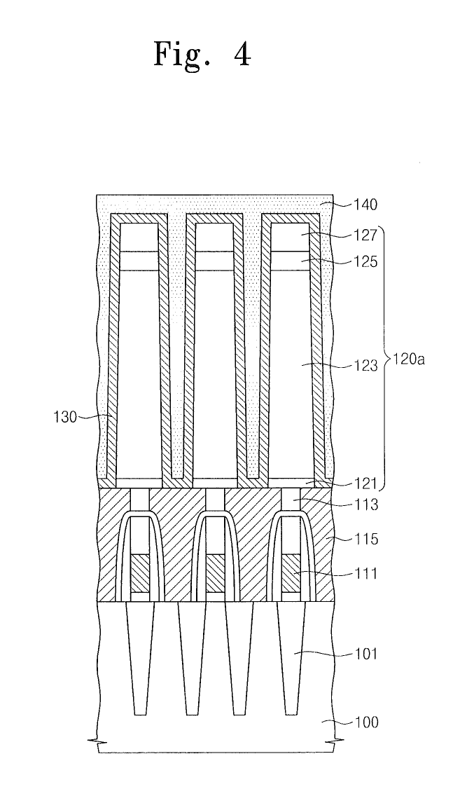

Referring to FIG. 4, a first conductive film 130 and a core support film 140 are sequentially formed on the first mold layer 120 including in the first openings 129. The first conductive film 130 and the core support film 140 may be conformally formed in the first opening 129 using a film formation technology having a superior property of step coverage such as a chemical vapor deposition (CVD), a physical vapor deposition (PVD) or an atomic layer deposition (ALD). More specifically, the first conductive film 130 may be deposited with a thickness less than half the diameter of the first opening 129. That is, the first conductive film 130 may fill a part of the first opening 129 and a thickness of a bottom portion covering a top surface of the contact plug 115 and a thickness of a sidewall portion covering an inner wall of the first opening 129 may be substantially equal. The core support film 140 may be deposited with a sufficient thickness to completely fill the remaining portion of the first opening 129 in which the first conductive film 130 is formed. For example, each of the first conductive film 130 and the core support film 140 may be deposited with a thickness of about 10 Å˜500 Å.

In an embodiment of the inventive concept, the first conductive film 130 may include at least one of doped silicon, metal materials, metal nitride films and metal silicides. For example, the first conductive film 130 may be formed from refractory metal such as cobalt, titanium, nickel, tungsten and molybdenum. The first conductive film 130 may be formed from a metal nitride film such as a titanium nitride film (TiN), a titanium silicon nitride film (TiSiN), a titanium aluminum nitride film (TiAlN), a tantalum nitride film (TaN), a tantalum silicon nitride film (TaSiN), a tantalum aluminum nitride film (TaAlN) and a tungsten nitride film (WN). The first conductive film 130 may also be formed from at least one noble metal film selected from the group consisting of platinum (Pt), ruthenium (Ru) and iridium (Ir). The first conductive film 130 may be formed from a noble metal conductive oxide film such as PtO, RuO₂ or IrO₂ and a conductive oxide film such as SRO(SrRuO₃), BSRO((Ba, Sr) RuO₃), CRO(CaRuO₃) or LSCo.

After depositing the first conductive film 130, a plasma treatment process and an annealing process for removing impurities generated when the first conductive film 130 is deposited may be performed. When performing a plasma treatment process, N₂ plasma and H₂ plasma may be used.

In an embodiment of the inventive concept, the core support film 140 may be formed from material having an etching selectivity with respect to the first conductive film 130 and the first mold layer 120a. More specifically, the core support film 140 may remain in a first conductive pattern of cylindrical shape to form a core support pattern preventing a lower electrode from collapsing and may be formed from material having a mechanical strength (e.g., stiffness) greater than the lower electrode material. In other words, the core support film 140 may be formed from material having modulus of elasticity greater than the lower electrode material. More specifically, the core support film 140 may be formed from material having Young's modulus of about 300 Gpa to 1000 Gpa. In an embodiment of the inventive concept, the core support film 140 may be selected from silicon doped with an impurity, metal materials, metal nitride films and metal silicides and may be formed from material having an etching selectivity with respect to the conductive film 130. In another embodiment of the inventive concept, the core support film 140 may be formed of at least one selected from the group consisting of silicon oxide, silicon nitride, silicon carbide (SiC), silicon oxycarbide (SiOC), SiLK, a black diamond, CORAL, BN, ARC (anti-reflective coating) film or combinations thereof.

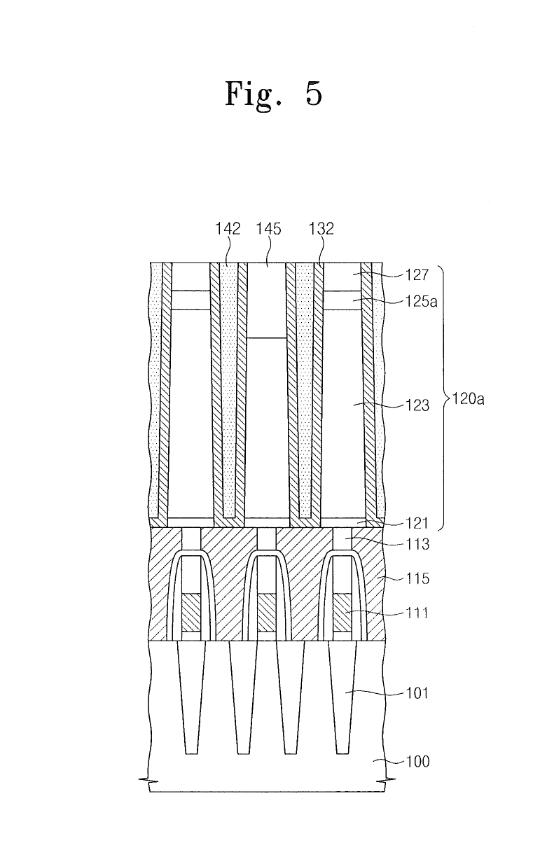

A planarization process is performed on the first conductive film 130 and the core support film 140 until a top surface of the first mold layer 120a is exposed. A chemical mechanical polishing (CMP) process or a dry etch-back process may be used as a planarization process. As illustrated in FIG. 5, a first conductive pattern 132 of cylindrical shape may be formed in each of the first openings 129 by planarizing the first conductive film 130 and the core support film 140, resulting in a core support pattern 142 in the first conductive pattern 132.

Also, after forming the first conductive patterns 132 and the core support patterns 142, the first support film 125 may be patterned to form a first support pattern 125a.

Forming the first support pattern 125a may include forming mask patterns exposing a part of the upper insulating film 127 on the first mold layer 120a in which the first conductive patterns 132 and the core support patterns 142 are formed and sequentially etching the upper insulating film 127 and the first support film 125 exposed to the mask pattern. Thus, the first support pattern 125a may be formed which is connected to the first conductive patterns 132 and exposes the lower insulating film 123 in predetermined regions. In other words, the first support pattern 125a may expose the lower insulating film 123 while surrounding an entire or a portion of a sidewall of the first conductive pattern 132. Since the first support pattern 125a has an etching selectivity with respect to the upper and lower insulating films 127 and 123 in a subsequent process of removing the upper and lower insulating films 127 and 123, the first support pattern 125a prevents the lower electrode having a great aspect ratio from collapsing by connecting the adjacent first conductive patterns 132. After forming the first support pattern 125a, an insulating film 145 may be formed on the lower insulating film 123 exposed between the first conductive patterns 132.

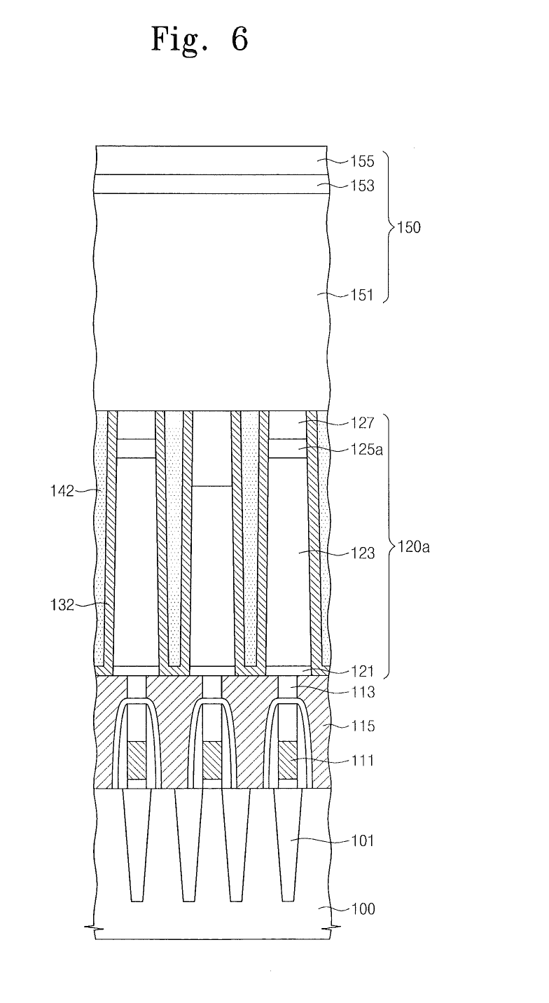

Referring to FIG. 6, a second mold layer 150 is formed on the first mold layer 120a in which the first conductive patterns 132 and the core support patterns 142 are formed. According to an embodiment of the inventive concept, the second mold layer 150 may have a thickness of about 5000 Å˜about 15000 Å. The second mold layer 150 may be comprised of a lower insulating film 151, a second support film 153 and an upper insulating film 155, similar to the first mold layer 120a. The lower and upper insulating films 151 and 155 may be formed from a silicon oxide film and the second support film 153 may be formed from a silicon nitride film. According to another embodiment of the inventive concept, the second support film 153 may be omitted and the second mold layer 150 may be comprised of one or a plurality of insulating films.

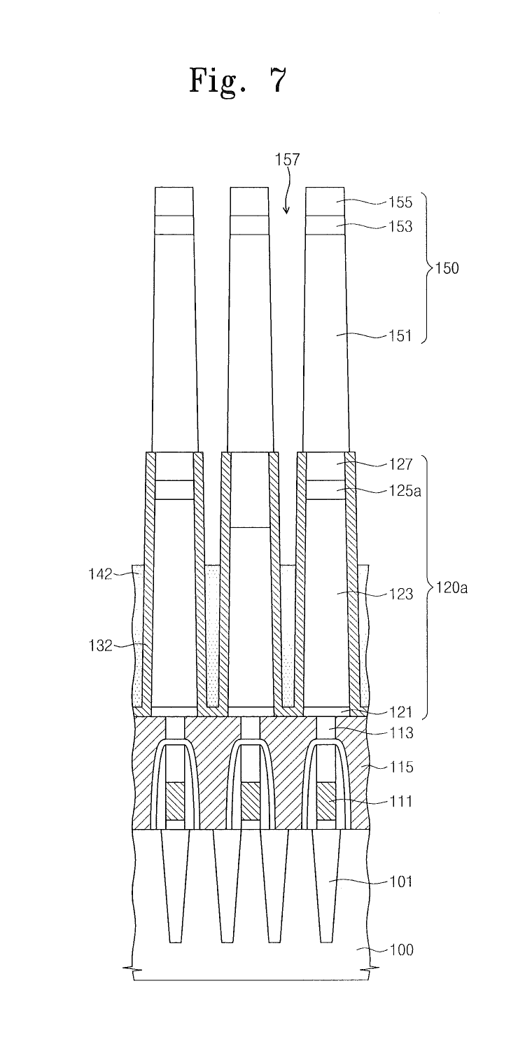

Referring to FIG. 7, the second mold layer 150 is patterned to form second openings 157 exposing the first conductive pattern 132 and the core support pattern 142. The second openings 157 may be formed by anisotropically etching the second mold layer 150 using the same mask pattern as the mask pattern for forming the first openings 129 as an etching mask. Due to the anisotropic etching, the first opening 157 may have a tapered width that becomes narrower closer to the bottom of the second opening 157.

Subsequently, a top surface of the core support pattern 142 exposed by the second opening 157 is recessed by a predetermined depth. More specifically, a top surface of the core support pattern 142 may be recessed by anisotropically or isotropically etching the core support pattern 142 using an etching recipe having an etching selectivity with respect to the first and second mold layers 120a and 150a and the first conductive pattern 132. As the top surface of the core support pattern 142 is recessed, the second opening 157 may expose a top surface of the first conductive pattern 132 and a part of an inner sidewall of the first conductive pattern 132. As the top surface of the core support pattern 142 is recessed, the core support pattern 142 may fill a part of the first conductive pattern 132 of cylindrical shape. A height of the core support pattern 142 may be about 1/3˜about 1/2 of a height of the first conductive pattern 132.

According to another embodiment of the inventive concept, recessing the core support pattern 142 may be performed until the first conductive pattern 132 under the core support pattern 142 is exposed. That is, the whole core support pattern 142 exposed by the second openings 157 may be removed. Accordingly, a surface of the first conductive pattern 132 under the core support pattern 142 may be exposed. That is, the inside of the first conducive pattern 132 of cylindrical shape having a groove region may be exposed.

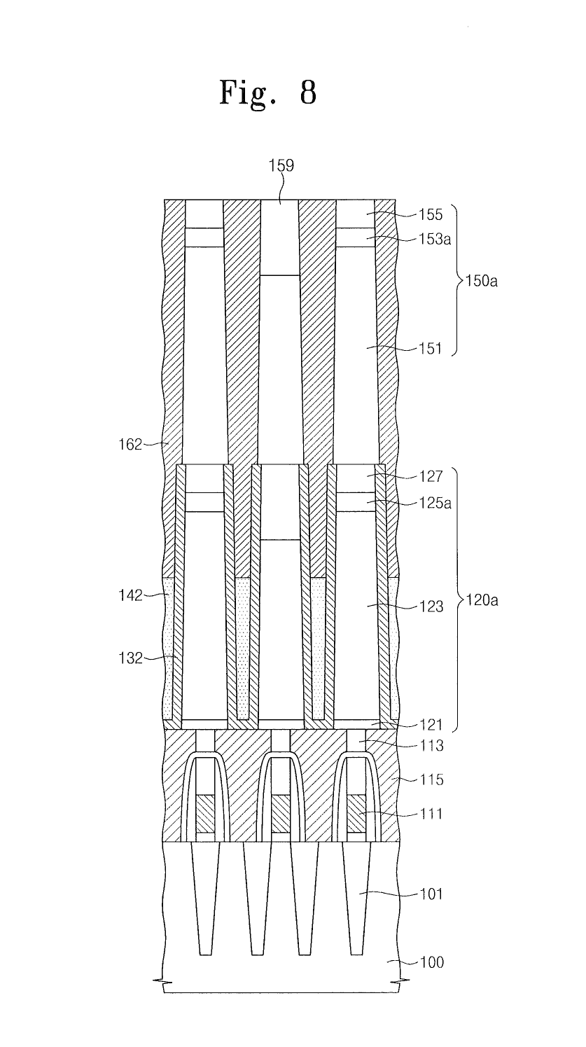

Referring to FIG. 8, a second conductive pattern 162 is formed in the second opening 157. The second conductive pattern 162 may be formed by depositing a second conductive film on the second mold layer 150a including in the second openings 157, and then planarizing the second conductive film. According to an embodiment of the inventive concept, the second conductive film may be deposited to have a thickness that can completely fill the second openings 157. According to another embodiment of the inventive concept, the second conductive film, for example like the first conductive film 130, may be conformally deposited while filling a part of the second openings 157. The second conductive film may be directly deposited on a part of inner sidewall of the first conductive pattern 132 exposed by the second openings 157. The second conductive film may include at least one of silicon doped with an impurity, metal materials, metal nitride films and metal silicides. For example, the second conductive film may be formed from refractory metal such as cobalt, titanium, nickel, tungsten and molybdenum. The second conductive film may be formed from at least one metal nitride film selected from the group consisting of a titanium nitride film (TiN), a titanium silicon nitride film (TiSiN), a titanium aluminum nitride film (TiAlN), a tantalum nitride film (TaN), a tantalum silicon nitride film (TaSiN), a tantalum aluminum nitride film (TaAlN) and a tungsten nitride film (WN). The second conductive film may also be formed from at least one noble metal film selected from the group consisting of platinum (Pt), ruthenium (Ru) and iridium (Ir). The second conductive film may be formed from a noble metal conductive oxide film such as PtO, RuO₂ or IrO₂ and a conductive oxide film such as SRO(SrRuO₃), BSRO((Ba, Sr) RuO₃), CRO(CaRuO₃) or LSCo.

After depositing the second conductive film, a plasma treatment process and an annealing process for removing impurities generated when the second conductive film is deposited may be performed. When performing a plasma treatment process, N₂ plasma and H₂ plasma may be used.

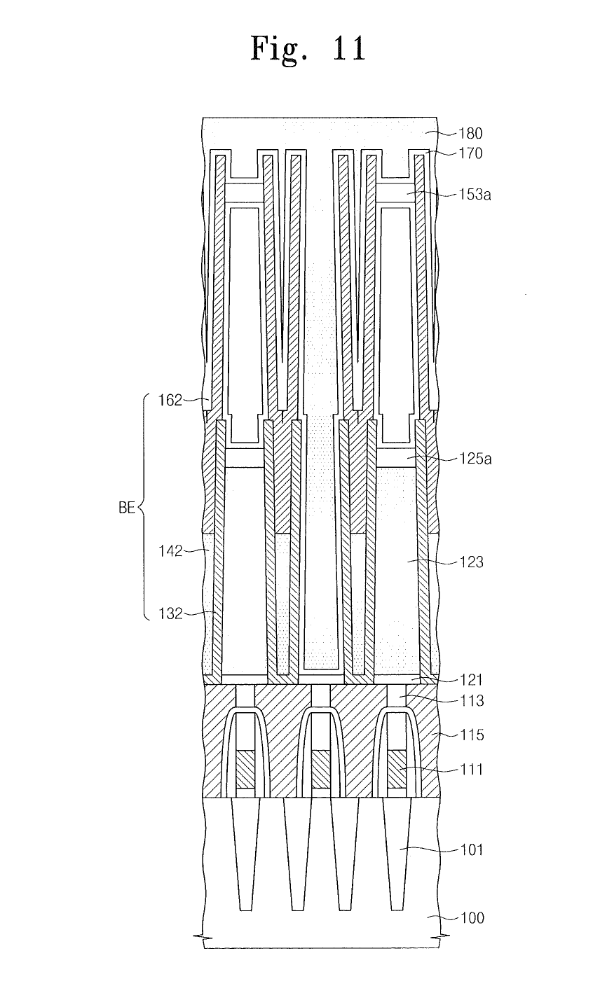

The second conductive film is planarized to form the second conductive pattern 162 in each of the second openings 157. In an embodiment of the inventive concept, the second conductive pattern 162 may have a pillar shape and may also have a cylindrical shape having a groove therein as illustrated in FIG. 11.

After forming the second conductive patterns 162, like forming the first support pattern 125a described with reference to FIG. 5, a second support pattern 153a may be formed by patterning the second support film 153. That is, the second support pattern 153a exposing the lower insulating film 151 of the second mold layer 150a may be formed while surrounding an entire or a portion of outer sidewall of the second conductive pattern 162. After forming the second support pattern 153a, an insulating film 159 may be formed on the lower insulating film 151 exposed between the second conductive patterns 162.

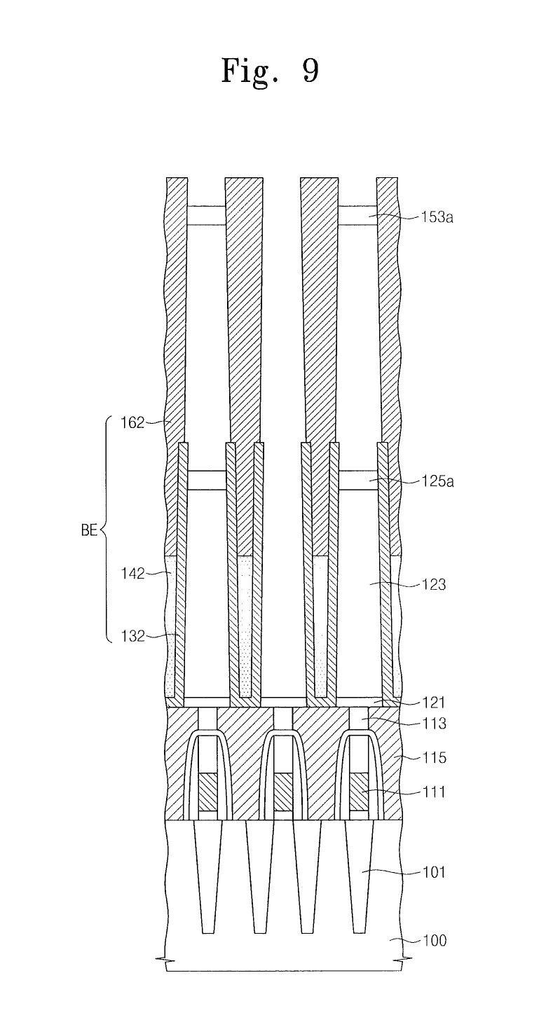

Referring to FIG. 9, an etching process selectively removing the first and second mold layers 120a and 150a may be performed. More specifically, in the case that the first and second mold layers 120a and 150a are formed from a silicon oxide film, the first and second mold layers 120a and 150a may be removed by a wet etching process using an etching solution including hydrofluoric acid. In the case that the first and second mold layers 120a and 150a are formed from a silicon nitride film, the first and second mold layers 120a and 150a may be removed by a wet etching process using an etching solution including nitric acid. Also, in the case that the first and second mold layers 120a and 150a are formed from a film of polymer system, the first and second mold layers 120a and 150a may be removed by a dry etching process at an oxygen atmosphere.

Outer sidewalls of he first and second conductive patterns 132 and 162 may be exposed by removing the first and second mold layers 120a and 150a. When removing the first and second mold layers 120a and 150a, the first and second support patterns 125a and 153a having an etching selectivity may remain. Thus, the adjacent first conductive patterns 132 may be connected by the first support pattern 125a and the adjacent conductive patterns 162 may be connected by the second support pattern 153a.

The first and second conductive patterns 132 and 162 of a multilayered structure may be electrically connected to be used as a lower electrode BE. According to the present embodiment of the inventive concept, the second conductive pattern 162 on the first conductive pattern 132 may be inserted into the first conductive pattern 132. As the second conductive pattern 162 is inserted into the first conductive pattern 132, a contact area between the first and second conductive patterns 132 and 162 may increase. Thus, after removing the first and second mold layers 120a and 150a, the second conductive pattern 162 may be prevented from collapsing on the first conductive pattern 132. That is, a lower electrode BE of capacitor may be prevented from being broken or being bent at a position where the first and second conductive patterns 132 and 162 are in contact with each other.

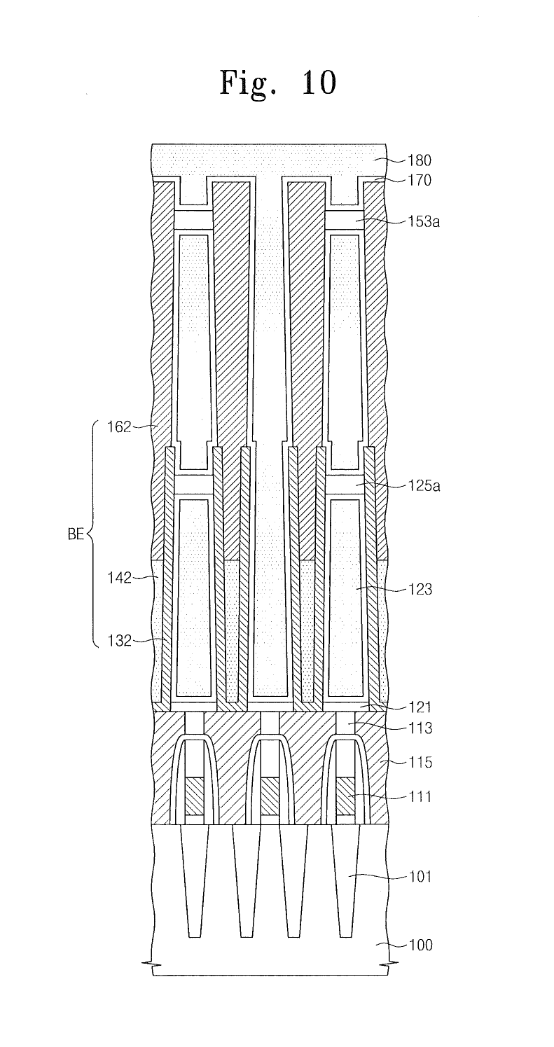

Referring to FIG. 10, a dielectric film 170 is conformally formed along a surface of the first and second conductive patterns 132 and 162 and an upper electrode 180 is formed on the dielectric film 170. The dielectric film 170 and the upper electrode 180 may be formed using a film formation technology having a superior property of step coverage such as a chemical vapor deposition (CVD), a physical vapor deposition (PVD) or an atomic layer deposition (ALD).

The dielectric film 170 may be formed of one selected from the group consisting of a metal oxide such as HfO₂, ZrO₂, AlO₃, LaO₃, TaO₃ and TiO₂ and a dielectric material of a perovskite structure such as SrTiO₃(STO), (Ba, Sr)TiO₃(BST), BaTiO₃, PZT, PLZT or combinations thereof. The dielectric film 170 may have a thickness of about 50 Å˜about 150 Å.

The upper electrode may include at least one of silicon doped with an impurity, metal materials, metal nitride films and metal silicides. For example, the upper electrode 180 may be formed from refractory metal such as cobalt, titanium, nickel, tungsten and molybdenum. The upper electrode 180 may be formed from a metal nitride film such as a titanium nitride film (TiN), a titanium silicon nitride film (TiSiN), a titanium aluminum nitride film (TiAlN), a tantalum nitride film (TaN), a tantalum silicon nitride film (TaSiN), a tantalum aluminum nitride film (TaAlN) and a tungsten nitride film (WN). The upper electrode 180 may also be formed from at least one noble metal film selected from the group consisting of platinum (Pt), ruthenium (Ru) and iridium (Ir). The upper electrode 180 may be formed from a noble metal conductive oxide film such as PtO, RuO₂ or IrO₂ and a conductive oxide film such as SRO(SrRuO₃), BSRO((Ba, Sr) RuO₃), CRO(CaRuO₃) or LSCo.

After depositing the upper electrode 180, a plasma treatment process and an annealing process for removing impurities generated when the first conductive film 130 is deposited may be performed. When performing a plasma treatment process, N₂ plasma and H₂ plasma may be used.

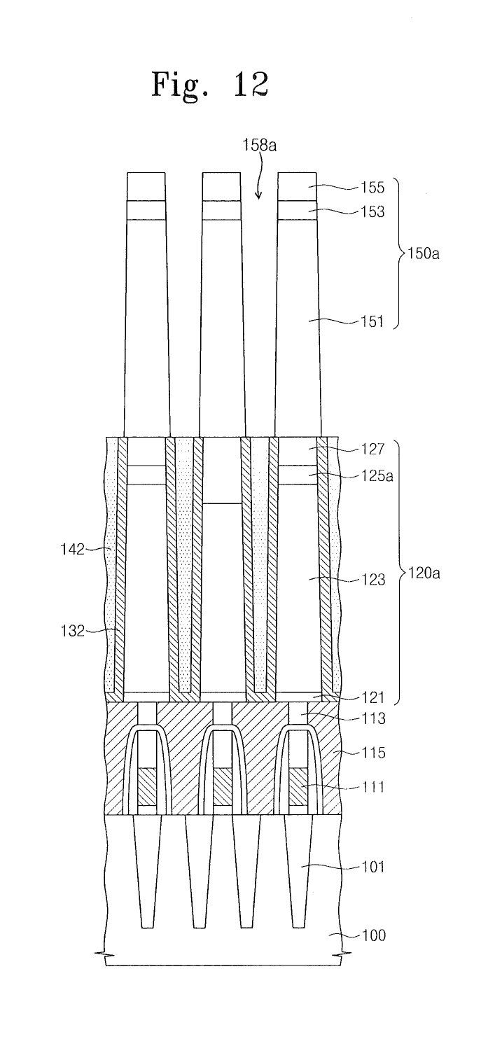

FIGS. 12 through 15 are cross sectional views for explaining methods of manufacturing capacitors of semiconductor devices in accordance with embodiments of the inventive concept.

According to the second embodiment of the inventive concept, as described with reference to FIGS. 6 and 7, a second mold layer 150 is formed on a first mold layer 120a in which first conductive patterns 132 and core support patterns 142 are formed. Referring to FIG. 12, the second mold layer 150 is patterned to form second openings 158a exposing the first conductive patterns 132 and the core support patterns 142. The second openings 158a may be formed by anisotropic ally etching the second mold layer 150 as described with reference to FIG. 7. As a result, a lower width of the second opening 158a may be smaller than an upper width of the second opening 158a.

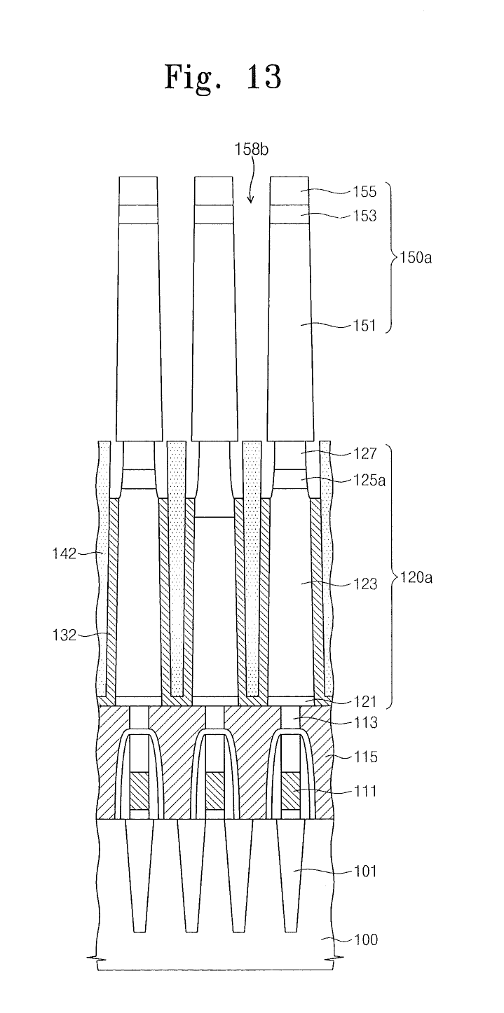

Referring to FIG. 13, a top surface of the first conductive pattern 132 exposed by the second opening 158a is recessed by a predetermined depth. More specifically, a top surface of the first conductive pattern 132 may be recessed by anisotropically or isotropically etching the first conductive pattern 132 using an etching recipe having an etching selectivity with respect to the first and second mold layers 120a and 150a and the core support pattern 142. As the top surface of the first conductive pattern 132 is recessed, a recessed region may be formed between the second mold layer 150a and the core support pattern 142. Herein, when etching the first conductive pattern 132, a part of the first mold layer 120a formed from insulating material may be etched. Also, when isotropically etching the first conductive pattern 132, a sidewall of the first mold layer 120a exposed by the recessed region may be rounded.

As a portion of the first conductive pattern 132 is etched, the second opening 158b may extend between the first mold layer 120a and the core support pattern 142 and may expose a part of an outer sidewall of the core support pattern 142 may be exposed. Thus, a lower width of the second opening 158b may be greater than an upper width of the second opening 158b. As a top surface of the first conductive pattern 132 is recessed, a height of the first conductive pattern 132 may become lower than a height of the core support pattern 142.

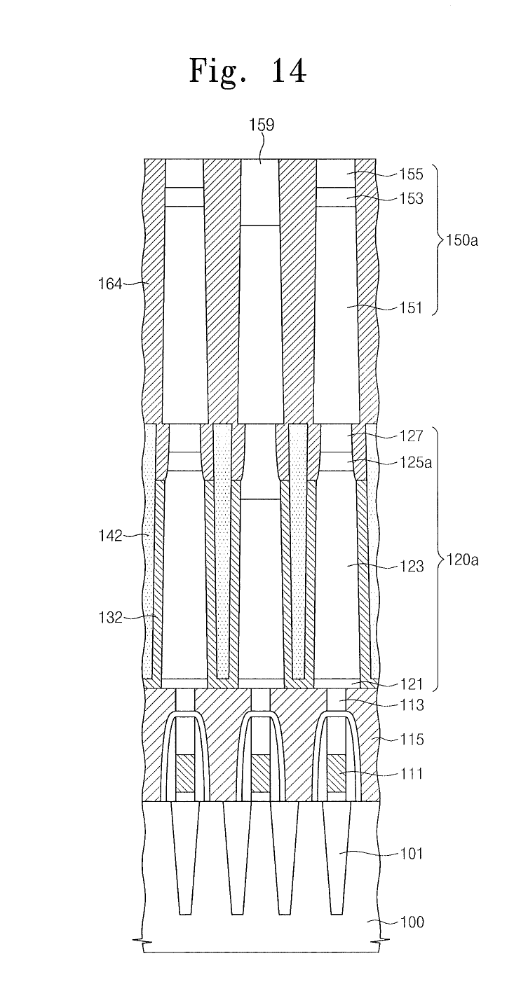

Referring to FIG. 14, a second conductive pattern 164 is formed in each of the second openings 158b. The second conductive pattern 164, as described with reference to FIG. 8, may be formed by depositing a second conductive film on the second mold layer 150a in which the second openings 158 are formed, and then planarizing the second conductive film. Herein, the second conductive film may be deposited to have a thickness that can completely fill the second openings 158b. Alternatively, the second conductive film may be conformally deposited to fill a part of the second openings 158b.

The second conductive pattern 164 may include a lower region surrounding the core support pattern 142 and an upper region on the core support pattern 142. A lower width of the second conductive pattern 164 may be greater than an upper width of the second conductive pattern 164.

A second support film is patterned to form a second support pattern 153a as forming the first support pattern 125a described with reference to FIG. 5. That is, the second support pattern 153a may be formed which exposes a lower insulating film 151 of the second mold layer 150a while surrounding an entire portion or a portion of an outer sidewall of the second conductive pattern 164.

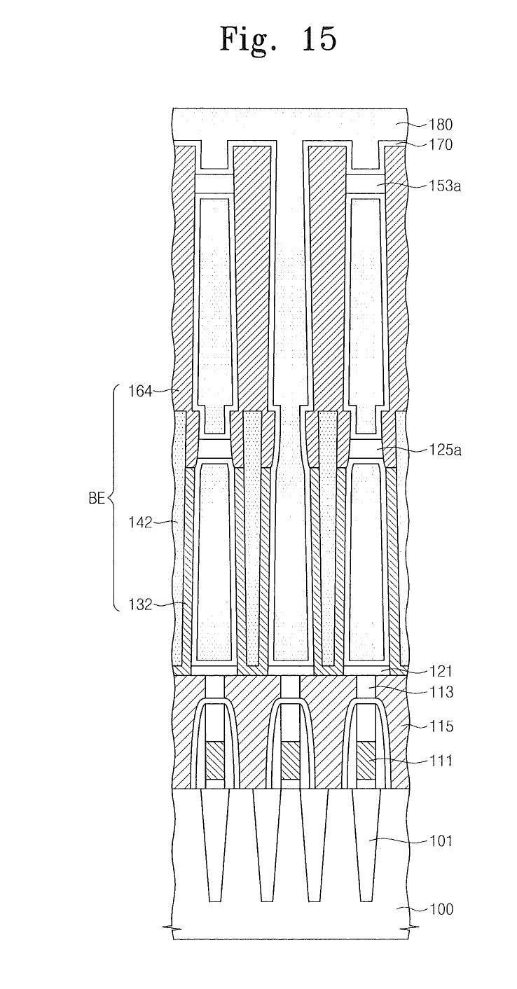

After that, referring to FIG. 15, as described with reference to FIG. 9, the first and second mold layers 120a and 150a are removed. Subsequently, as described with reference to FIG. 10, a dielectric film 170 is conformally formed along a surface of the first and second conductive patterns 132 and 164 and an upper electrode 180 is formed on the dielectric film 170.

According to an embodiment of the inventive concept, a lower electrode BE of capacitor, may include the first and second conductive patterns 132 and 164 of a multilayered structure that are electrically connected to each other. The core support pattern 142 may be buried in the lower electrode BE by the first and second conductive patterns 132 and 164. Herein, the core support pattern 142 may extend on the first conductive pattern 132 and may be inserted into a lower part of the second conductive pattern 164. That is, the second conductive pattern 164 is located on the core support pattern 142 and may extend toward the outer sidewall of the core support pattern 142. Accordingly, a contact area between the second conductive pattern 164 and the core support pattern 142 increases and thereby the second conductive pattern 164 may be prevented from collapsing or being bent on the first conductive pattern 132 after removing the first and second mold layers 120a and 150a.

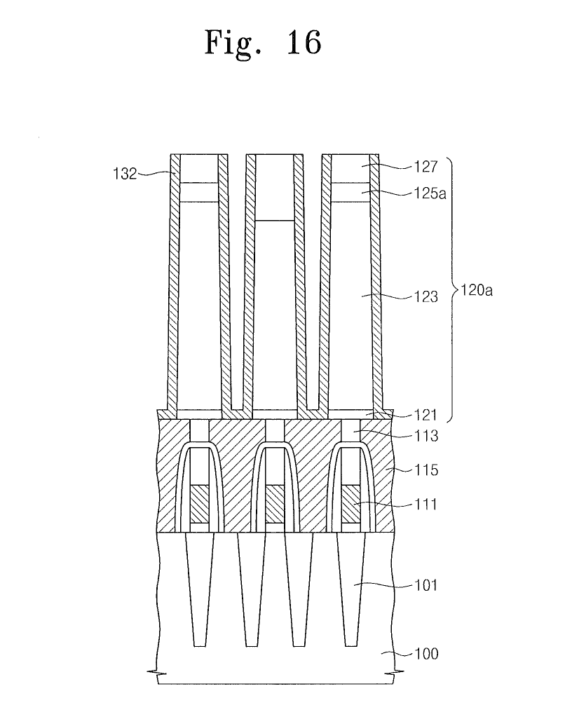

Referring to FIGS. 16 through 20, methods of manufacturing capacitors of semiconductor memory devices in accordance with embodiments of the inventive concept are described.

FIGS. 16 through 20 are cross sectional views for explaining methods of manufacturing capacitors of semiconductor devices in accordance with embodiments of the inventive concept.

In some embodiments of the inventive concept, as described for example with reference to FIG. 3, a first mold layer 120 is patterned to form first openings 129 exposing contact plugs 115 and a first conductive pattern 132 is formed in the first opening 129. In the present embodiment of the inventive concept, the first conductive pattern 132 may be formed by conformally depositing a first conductive film on the first mold layer 120 in which the first opening 129 is defined, and then removing the first conductive film on a top surface of the first mold layer 120 using an etching process such as an etch-back process. As a result, a first conductive pattern 132 including a bottom portion and a sidewall portion defining a groove region in the first opening 129 and having a uniform thickness may be formed.

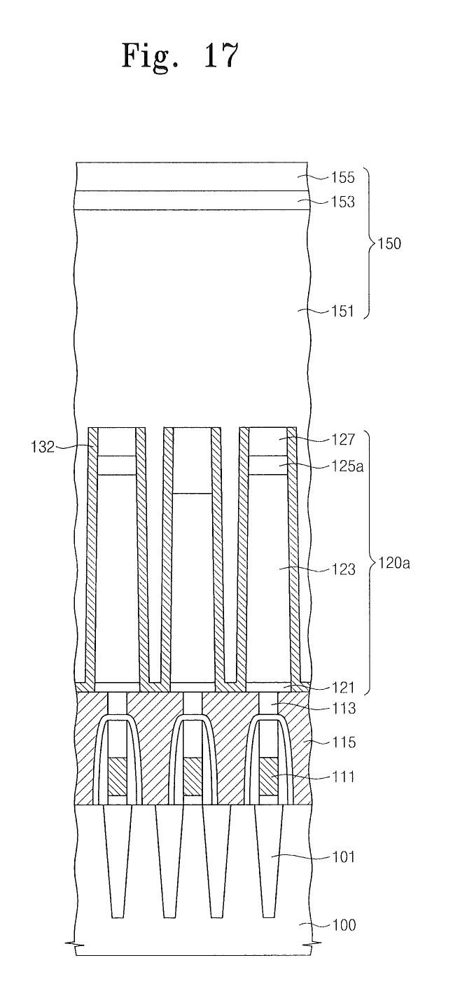

As described with reference to FIG. 6, a second mold layer 150 is formed on the first mold layer 120a in which the first conductive patterns 132 are formed. Similar to the first mold layer 120a, the second mold layer 150 may be comprised of a lower insulating film 151, a second support film 153 and an upper insulating film 155, and the lower and upper insulating films 151 and 155 may be formed from a silicon oxide film and the second support film 153 may be formed from a silicon nitride film. According to another embodiment of the inventive concept, the second support film 153 may be omitted and the second mold layer 150 may be comprised of one or a plurality of insulating films. In the present embodiment of the inventive concept, the lower insulating film 151 of the second mold layer 150, as illustrated in FIG. 17, may fill the groove defined by the first conductive pattern 132.

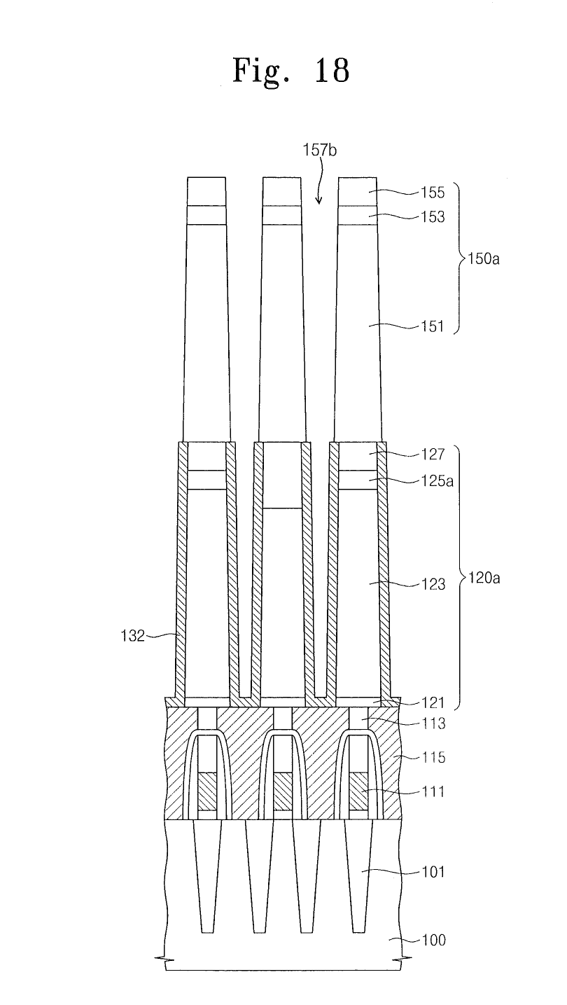

Referring to FIG. 18, as described with reference to FIG. 7, the second mold layer 150 is patterned to form second openings 157b exposing the first conductive pattern 132. The second openings 157b may be formed by anisotropically etching the second mold layer 150 using a mask pattern (not shown) on the second mold layer 150. Forming the second opening 157b by patterning the second mold layer 150 includes etching the second mold layer 150 on the first conductive pattern 132 so that the inside of the first conductive pattern 132 is exposed.

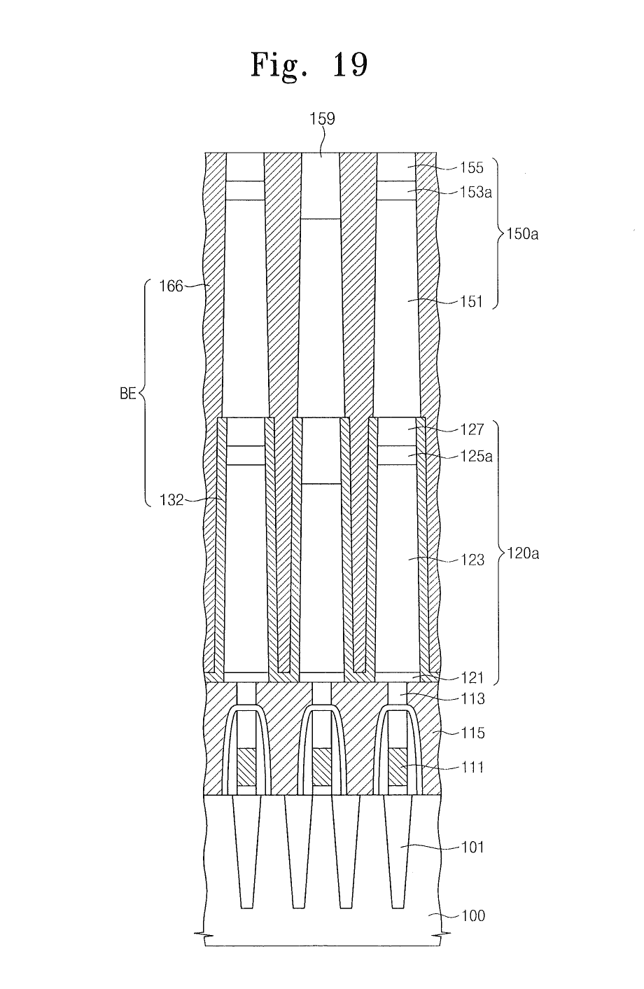

Referring to FIG. 19, a second conductive pattern 166 is formed in each of the second openings 157b. The second conductive pattern 166, as described with reference to FIG. 8, may be formed by depositing a second conductive film on the second mold layer 150a in which the second openings 157 are formed and then planarizing the second conductive film. According to an embodiment of the inventive concept, the second conductive film may be deposited to have a thickness that can completely fill the second openings 157b. That is, the second conductive pattern 166 may fill the inside of the first conductive pattern 132. According to another embodiment, the second conductive film, as illustrated in FIG. 11, may be conformally deposited in the second opening 157b. That is, the second conductive film may be conformally deposited on an inner wall of the first conductive pattern 132 and an inner wall of the second opening 157b.

In some embodiments according to the invention, a lower electrode BE of capacitor, like the first and second embodiments, includes the first and second conductive patterns 132 and 166 of a multilayer structure that are electrically connected to each other. The second conductive pattern 166 formed on the first conductive pattern 132 may have a structure to be inserted into the first conductive pattern 132. Herein, the second conductive pattern 166 may be directly in contact with the whole inner wall of the first conductive pattern 132. Therefore, after removing the first and second mold layers 120a and 150a, the second conductive pattern 166 may be prevented from collapsing on the first conductive pattern 132.

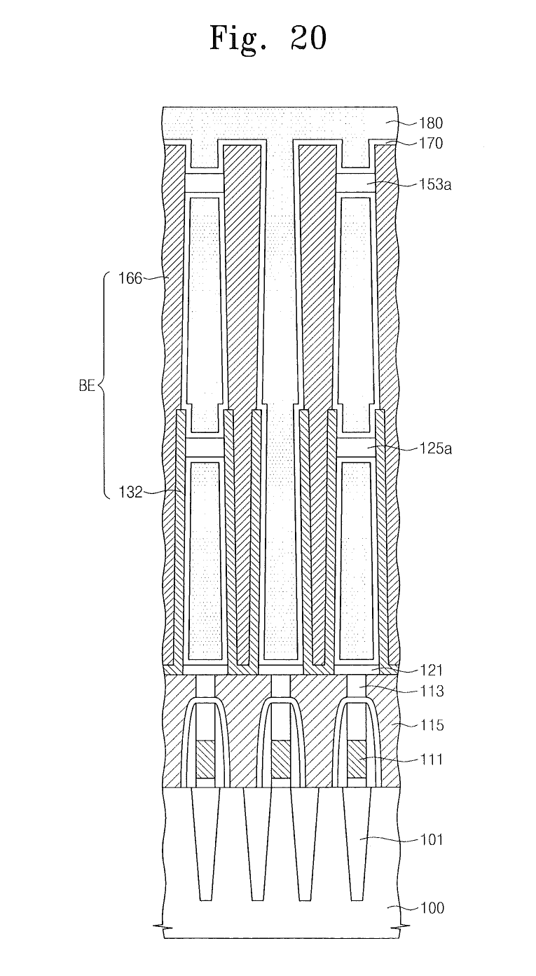

Referring to FIG. 20, as described for example with reference to FIG. 9, the first and second mold layers 120a and 150a are removed. Subsequently, as described for example with reference to FIG. 10, a dielectric film 170 is formed along surfaces of the first and second conductive patterns 132 and 166 and an upper electrode 180 is formed on the dielectric film 170.

According to exemplary embodiments of the inventive concept, forming a lower electrode of a multilayer structure increases a surface area of the lower electrode, thereby increasing a capacitance of capacitor. In a lower electrode of capacitor including a first conductive pattern and a second conductive pattern on the first conductive pattern, a lower electrode having a great aspect ratio may be prevented from collapsing by forming a core support pattern formed from a superior mechanical strength in the first conductive pattern. Further, as the second conductive pattern is inserted into the first conductive pattern, a contact area between the first and second conductive patterns increases, thereby preventing the lower electrode from collapsing.

Although the present inventive concept has been described in connection with the embodiments of the present inventive concept illustrated in the accompanying drawings, it is not limited thereto. It will be apparent to those skilled in the art that various substitutions, modifications and changes may be made thereto without departing from the scope and spirit of the inventive concept.

1. A capacitor of semiconductor device comprising:
a lower electrode on a semiconductor substrate;
a dielectric film covering a surface of the lower electrode: and
an upper electrode covering the dielectric film,
wherein the lower electrode comprises:
a first conductive pattern comprising a bottom portion and an interior sidewall portion defining a groove region;
a core support pattern in the groove region of the first conductive pattern; and
a second conductive pattern electrically connected to the first conductive pattern on the core support pattern.

2. The capacitor of claim 1, wherein a bottom surface of the second conductive pattern is lower than a top surface of the first conductive pattern.

3. The capacitor of claim 1, wherein the core support pattern is separated from the dielectric film and the upper electrode by the first conductive pattern and the second conductive pattern.

4. The capacitor of claim 1, wherein the core support pattern and the first conductive pattern are formed from different materials.

5. The capacitor of claim 1, wherein the core support pattern material comprises a material having a mechanical strength greater than that of the first conductive pattern.

6. The capacitor of claim 1, wherein a thickness of the first conductive pattern at the bottom of the groove is substantially equal to a thickness of the interior sidewall portion of the first conductive pattern.

7. The capacitor of claim 1, wherein a height of the core support pattern is less than a height of the first conductive pattern and wherein the second conductive pattern is in contact with a portion of an inner wall of the first conductive pattern.

8. The capacitor of claim 1, wherein a height of the core support pattern is greater than a height of the first conductive pattern and wherein the second conductive pattern surrounds a portion of an outer wall of the core support pattern.

9. The capacitor of claim 8, wherein a lower width of the second conductive pattern is greater than an upper width of the second conductive pattern.

10. The capacitor of claim 8, wherein a lower width of the second conductive pattern is greater than an upper width of the first conductive pattern.

11. The capacitor of claim 1, further comprising a support pattern connecting the first conductive pattern and the adjacent first conductive patterns, wherein a bottom surface of the second conductive pattern is lower than the support pattern.

12.-15. (canceled)

16. A lower electrode of a capacitor in a semiconductor device comprising:
a first conductive pattern, on a semiconductor substrate of the device, including a groove region therein electrically contacting an underlying contact plug at a bottom of the first conductive pattern; and
a second conductive pattern, separate from the first conductive pattern, extending into the groove region to the bottom of the first conductive pattern.

17. The lower electrode according to claim 16 further comprising:
a first support film contacting an upper portion of an outer surface of the first conductive pattern configured to support the first conductive pattern during formation of the lower electrode.

18. The lower electrode according to claim 17 further comprising:
a second support film contacting an upper portion of an outer surface of the second conductive pattern configured to support the second conductive pattern during formation of the lower electrode.

19. The lower electrode according to claim 16 wherein a width of the first conductive pattern where the second conductive pattern enters the groove region is greater than a width of the second conductive pattern.

20. The lower electrode according to claim 16 wherein the second conductive pattern extends from above and outside the groove region into the groove region.
